(19) United States
(12) Patent Application Publication
(10) Pub. No.: US 2026/0107427 A1
(43) Pub. Date: Apr. 16, 2026

(54) COMPONENT MOUNTING SYSTEM AND MOUNTING TOOL FEEDER

(71) Applicant: FUJI CORPORATION, Chiryu (JP)

(72) Inventor: Mizuho NOZAWA, Kota-cho (JP)

(73) Assignee: FUJI CORPORATION, Chiryu (JP)

(21) Appl. No.: 19/114,588

(22) PCT Filed: Oct. 14, 2022
(86) PCT No.: PCT/JP2022/038369

§ 371 Date: Mar. 24, 2025

(51) Int. Cl. H05K 13/08; H05K 13/04

(52) U.S. Cl. CPC H05K 13/085; H05K 13/0409

(57) ABSTRACT

A component mounting system includes multiple component mounters configured to each hold component mounting tools in an automatically exchangeable manner, a conveyance device configured to convey the component mounting tools between a storage area configured to store the component mounting tools, and a plan creation section configured to create a conveyance plan for the component mounting tools using the conveyance device based on a production plan indicating a type and a production order of the board product, and setup information indicating the types and quantities of the component mounting tools used by each of the multiple component mounters for each type of the board product or maintenance information indicating the maintenance timing of the component mounting tools.

### TECHNICAL FIELD

The present description relates to a component mounting system including multiple component mounters configuring a production line of a board product, and a mounting tool feeder applicable to the component mounting system.

### BACKGROUND ART

A technique for mass-producing board products by performing board work on a board on which a circuit pattern is formed is widespread. Further, it is common to arrange multiple types of board work machines side by side with each other to configure a production line for board products. As a representative example of a board work machine, there is a component mounter for mounting a component on a board. A large number of component mounters use suction nozzles as component mounting tools used in mounting components. Since a type and size of a component to be mounted are different for each type of a board product, a component mounter exchanges the suction nozzles with multiple types of suction nozzles respectively matching sizes of the various components and uses the suction nozzles. Technology for providing an automatic exchange function of a suction nozzle on a component mounter or a production line has been developed, and related art examples are disclosed in Patent Literatures 1 to 4.

Patent Literature 1 discloses a component mounter including an in-machine nozzle station that accommodates a suction nozzle and is disposed within a moving range of a mounting head, a nozzle exchange unit that accommodates a suction nozzle and is set in a feeder set section in an exchangeable manner, and a control device that selects and executes automatic exchange of a suction nozzle between the mounting head and the in-machine nozzle station and automatic exchange of a suction nozzle between the mounting head and the nozzle exchange unit. Further, there is disclosed a management system for a component mounting line, the system including an automatic exchange device that automatically exchanges a nozzle exchange unit in a feeder set section of multiple component mounters configuring the component mounting line, and a production management device that sets an empty nozzle exchange unit present in a line using the automatic exchange device when the empty nozzle exchange unit is requested from any one of the component mounters. According to this, it is possible to avoid an increase in a size and the number of the in-machine nozzle station and the nozzle exchange unit, and to address an increase in the number of suction nozzles for exchange while satisfying a request for saving a space.

Patent Literature 2 discloses a cassette-type nozzle exchange unit that is a form of the nozzle exchange unit. Further, Patent Literature 3 discloses a component supply device that stores a tool tray accommodating a component holding tool (suction nozzle) and supplies the tool tray to a component supply position in place of a part tray accommodating an electronic component as another form of the nozzle exchange unit. Patent Literature 4 discloses a nozzle cleaning device that receives an in-machine nozzle station removed from a component mounter and performs maintenance of a suction nozzle.

### CITATION LIST

### Patent Literature

Patent Literature 1: Japanese Patent No. 6870070

Patent Literature 2: Japanese Patent No. 6037581

Patent Literature 3: JP-A-2000-91795

Patent Literature 4: JP-A-2020-74447

### BRIEF SUMMARY

### Technical Problem

In the component mounter of Patent Literature 1, it is preferable that it is possible to address the increase in the number of the suction nozzles for exchange by accommodating the suction nozzles in multiple locations (the in-machine nozzle station and the nozzle exchange unit). Technical examples of Patent Literatures 2 and 3 are based on the same technical idea. However, in general, it is necessary to exchange the suction nozzle every time a type of a board product is changed, and an exchange frequency tends to be increased in a production form of high-variety, low-quantity production in particular. Therefore, in order to address the increase in the number of suction nozzles, it is necessary not only to enhance a device configuration but also to improve an operation technology for making it possible to use a limited number of suction nozzles in a planned and efficient manner. In addition, it is important to timely perform maintenance of the suction nozzle on both sides of an efficient operation and maintaining mounting reliability.

Therefore, in the present description, an object is to provide a component mounting system capable of creating a conveyance plan for conveying component mounting tools in a production line of a board product in a planned manner and efficiently operating the component mounting tools, and to provide a mounting tool feeder applicable to the component mounting system and capable of supplying the component mounting tools in an exchangeable manner.

### Solution to Problem

The present description discloses a component mounting system including: multiple component mounters configured to each hold component mounting tools used in mounting a component on a board at a predetermined exchange position inside the component mounter in an automatically exchangeable manner, the component mounters being arranged side by side with each other to configure a production line for board products; a conveyance device configured to convey the component mounting tools between a storage area configured to store the component mounting tools either outside the component mounter or inside the component mounter excluding the exchange position and the exchange position of the component mounter, and between the exchange positions of the multiple component mounters; and a plan creation section configured to create a conveyance plan for the component mounting tools using the conveyance device based on a production plan indicating a type and a production order of the board product, and setup information indicating the types and quantities of the component mounting tools used by each of the multiple component mounters for each type of the board product or maintenance information indicating the maintenance timing of the component mounting tools.

Further, the present description discloses a mounting tool feeder including: a mounting tool holding unit configured to detachably hold component mounting tools that a component mounter uses in mounting a component on a board, the mounting tool holding unit having the same configuration as a configuration of a mounting tool station disposed at a predetermined first exchange position in which automatic exchange of the component mounting tools is enabled inside the component mounter; and an attachment section detachably attached to the component mounter such that the mounting tool holding unit is disposed at a predetermined second exchange position inside the component mounter.

Furthermore, the present description discloses a mounting tool feeder including: a mounting tool holding unit configured to detachably hold component mounting tools that a component mounter uses in mounting a component on a board; an accommodation magazine configured to accommodate multiple mounting tool holding units; an exchange mechanism configured to selectively take out the mounting tool holding unit from the accommodation magazine and dispose the mounting tool holding unit at a predetermined exchange position in which automatic exchange of the component mounting tools is enabled inside the component mounter; and an attachment section attached to the component mounter.

### Advantageous Effects

In the disclosed component mounting system, the plan creation section creates the conveyance plan of the suction nozzle based on the production plan of the board product, and the setup information or maintenance information. According to this, the component mounting system is capable of creating the conveyance plan for conveying the component mounting tools of a type and the number required in the production line in a planned manner without excess or shortfall, or for timely conveying and efficiently operating the component mounting tools for which a maintenance timing has come. Further, the disclosed mounting tool feeder is applicable to the component mounter configuring the component mounting system, and is capable of supplying the component mounting tools in an exchangeable manner.

### BRIEF DESCRIPTION OF DRAWINGS

FIG. 1 is a plan view illustrating an overall configuration example of a component mounter configuring a production line of a board product.

FIG. 2 is a side view of a tape feeder detachably attached to the component mounter.

FIG. 3 is a perspective view showing a suction nozzle as a form of a component mounting tool.

FIG. 4 is a perspective view of a nozzle feeder (mounting tool feeder) which is detachably attached to the component mounter and supplies the suction nozzle (component mounting tool).

FIG. 5 is a perspective view of a nozzle holding unit (mounting tool holding unit) provided in the nozzle feeder in FIG. 4.

FIG. 6 is a cross-sectional side view showing a state in which the nozzle holding unit holds the suction nozzle.

FIG. 7 is a perspective view schematically showing the production line of the board product and a conveyance device.

FIG. 8 is a block diagram illustrating a configuration related to control of a component mounting system according to a first embodiment.

FIG. 9 is a diagram of an operation flow illustrating an operation of the component mounting system.

FIG. 10 is a table illustrating a production plan and setup information acquired by a plan creation section as an example.

FIG. 11 is a diagram illustrating an outline conveyance plan created by the plan creation section.

FIG. 12 is a diagram illustrating a detailed conveyance plan created by the plan creation section.

FIG. 13 is a perspective view of a nozzle feeder according to an application example.

FIG. 14 is a perspective view schematically showing a configuration of a component mounting system according to a second embodiment.

### DESCRIPTION OF EMBODIMENTS

### 1. Overall Configuration Example of Component Mounter 93

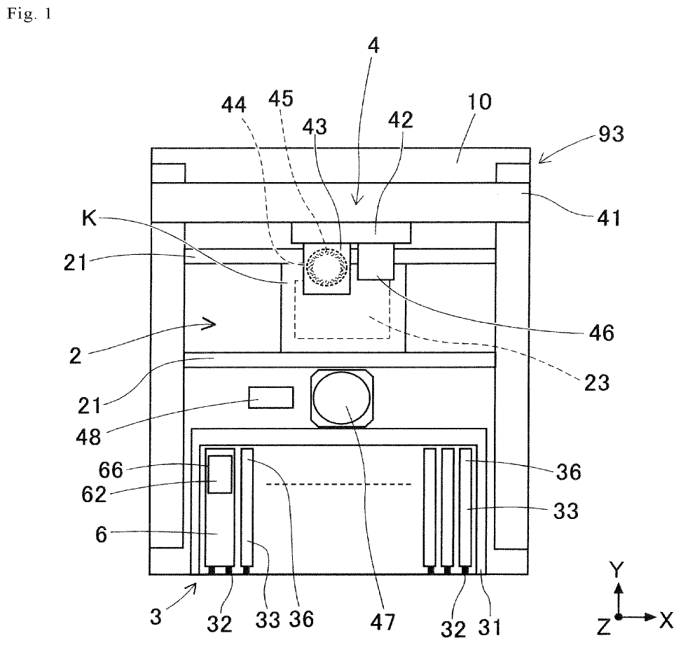

First, an overall configuration example of component mounter 93 configuring component mounting system 1 according to a first embodiment will be described with reference to FIG. 1. Component mounter 93 performs mounting work for mounting a component on board K. A horizontal direction from a left side toward a right side on the drawing surface in FIG. 1 is an X-axis direction in which board K is conveyed, a horizontal direction from a lower side (front side) toward an upper side (rear side) on the drawing surface is a Y-axis direction, and a vertical direction is a Z-axis direction. Component mounter 93 is configured by assembling board conveyance device 2, component supply device 3, component transfer device 4, control device 5 (refer to FIG. 8), and the like to base 10.

Board conveyance device 2 includes pair of guide rails 21, a pair of conveyance belts (not shown), clamp mechanism 23, and the like. Pair of guide rails 21 extends in a conveyance direction (X-axis direction) across the center of an upper surface of base 10, and is assembled to base 10 in parallel with each other. The pair of conveyance belts rotates along guide rails 21 in a state where two parallel sides of board K are placed, and carry in board K to a stop position in the vicinity of the center of base 10. Clamp mechanism 23 pushes up conveyed board K, clamps and positions board K between guide rails 21. After the mounting work of a component performed by component transfer device 4 is ended, clamp mechanism 23 releases board K, and the conveyance belts carry out board K to an outside of the device.

Component supply device 3 is disposed at a front portion of the upper surface of base 10 in the Y-axis direction. Component supply device 3 includes pallet table 31 and multiple tape feeders 33. Pallet table 31 is formed in a generally rectangular shape in plan view. Pallet table 31 includes multiple slots 32 extending in parallel in the Y-axis direction while being separated from each other. Each of multiple tape feeders 33 is inserted into and detachably attached to slot 32. Tape feeder 33 feeds a carrier tape in which multiple components are accommodated in a row toward supply position 36 on the rear, and supplies the components such that the components are collectable at supply position 36. Details of tape feeder 33 will be described later. A component feeder other than tape feeder 33 for example, a tray feeder using a tray accommodating multiple components in a two-dimensional grid shape, or a stick feeder using a cylindrical stick accommodating multiple components in a row may be detachably attached to pallet table 31.

Component transfer device 4 includes Y-axis moving body 41, X-axis moving body 42, mounting head 43, nozzle tool 44, multiple suction nozzles 45, board camera 46, part camera 47, nozzle station 48, and the like. Y-axis moving body 41 is formed of a member elongated in the X-axis direction, and is driven by a Y-axis direction drive mechanism to move in the Y-axis direction. X-axis moving body 42 is mounted on Y-axis moving body 41, is driven by an X-axis direction drive mechanism, and moves in the X-axis direction. Mounting head 43 is attached to a front surface of X-axis moving body 42. Mounting head 43 is driven in the horizontal two directions together with X-axis moving body 42 and moves to positions above component supply device 3 and above board K.

Nozzle tool 44 as a rotationally symmetric body is provided on a lower side of mounting head 43. Nozzle tool 44 is driven by an R-axis drive mechanism (not shown) to rotate about a vertical central axis. Nozzle tool 44 includes multiple (20 in the example of FIG. 1) suction nozzles 45 at an equal distance from the vertical central axis and in an automatically exchangeable manner. Suction nozzle 45 is driven by a lifting and lowering drive mechanism (not shown) to be lifted and lowered, and is driven by a Q-axis drive mechanism (not shown) to rotate about a vertical axis. Suction nozzle 45 is further selectively supplied with negative pressure air and positive pressure air from an air supply mechanism. As a result, suction nozzle 45 performs a pickup process of picking up the component from component supply device 3 and a mounting process of mounting the component on board K at the stop position. In mounting head 43, nozzle tool 44 may be omitted, and multiple suction nozzles 45 may be arranged in a row, or may be arranged in a grid shape. In addition, a component mounting tool other than suction nozzle 45, for example, a chuck-type mounting tool for gripping a component may be provided in mounting head 43 in an automatically exchangeable manner.

Board camera 46 is provided facing downward on X-axis moving body 42 side by side with mounting head 43. Board camera 46 images a position reference mark attached to board K from above. Acquired image data is subjected to image processing, so that the stop position of board K is accurately obtained. Part camera 47 is provided facing upward on base 10 between board conveyance device 2 and component supply device 3. Part camera 47 images the component held by suction nozzle 45 from below and recognizes the component while mounting head 43 moves from component supply device 3 to board K. As a result, it is determined whether the type of the component is correct or incorrect, and the position and orientation of the component with respect to suction nozzle 45 are detected and reflected in the mounting process. Examples of board camera 46 and part camera 47 include a digital imaging device including an imaging element such as a charge-coupled device (CCD) or a complementary metal-oxide semiconductor (CMOS).

Nozzle station 48 (mounting tool station) is detachably provided adjacent to part camera 47 between board conveyance device 2 and component supply device 3. Nozzle station 48 holds multiple suction nozzles 45 in an automatically exchangeable manner. Mounting head 43 sequentially performs the automatic exchange of suction nozzles 45 one by one, as mounting head 43 moves to nozzle station 48. Accordingly, an attachment position of nozzle station 48 is a predetermined first exchange position inside the device in which mounting head 43 performs the automatic exchange of suction nozzle 45. Multiple types of suction nozzles 45 are used through the automatic exchange, and it is possible to automatically address various sizes of components. The attachment and removal of nozzle station 48 are performed by a worker when component mounter 93 is not operating.

Control device 5 is assembled to base 10, and a disposition position thereof is not particularly limited. Control device 5 includes a computer device. Control device 5 may be configured such that multiple CPUs are distributed and disposed inside the device and are connected in communication with each other. Control device 5 controls board conveyance device 2, component supply device 3, and component transfer device 4 based on mounting work data created for each type of the board product, and advances the mounting work for the component. The mounting work data describes a detailed procedure of the mounting work.

### 2. Configuration of Tape Feeder 33

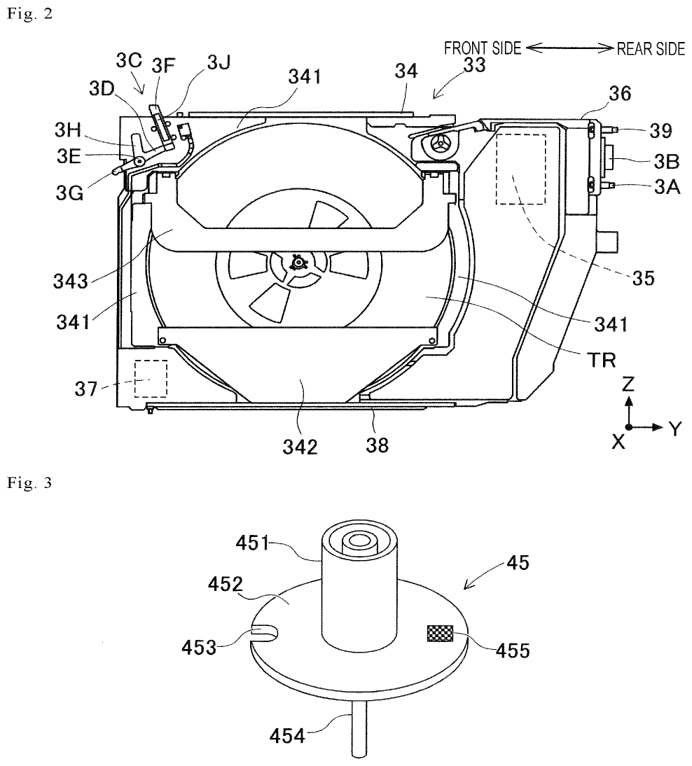

Next, a configuration of tape feeder 33 will be described with reference to FIG. 2. Tape feeder 33 is formed to be thin in a width direction (X-axis direction) by assembling various members to frame body 34 including a side plate. Tape feeder 33 includes frame body 34, tape feed mechanism 35, supply position 36, feeder control section 37, protrusion 38, upper positioning pin 39, lower positioning pin 3A, connector 3B, and lock mechanism 3C.

Frame body 34 includes reel accommodation frame 341, accommodation plate 342, and opening/closing plate 343. Reel accommodation frame 341 is a multiple of members that form a large circular internal space substantially at the center of frame body 34. Reel accommodation frame 341 rotatably accommodates tape reel TR in the internal space. Accommodation plate 342 for preventing detachment of tape reel TR is attached to a position below reel accommodation frame 341. Opening/closing plate 343 that can perform an opening/closing operation is attached to a position above an intermediate height of reel accommodation frame 341. By opening opening/closing plate 343, tape reel TR can be taken in and out. A carrier tape accommodating multiple components in a row is wound around tape reel TR.

Tape feed mechanism 35 is provided at a rear upper portion of frame body 34. Tape feed mechanism 35 pulls out the carrier tape from tape reel TR and feeds the carrier tape toward supply position 36 provided at a rear portion of an upper surface of frame body 34. Tape feed mechanism 35 includes a sprocket that fits into feeding holes of the carrier tape, a motor that drives and rotates the sprocket, and the like. Feeder control section 37 is disposed at a lower front portion of frame body 34 and may be disposed at another position. Feeder control section 37 controls tape feed mechanism 35 and monitors a state of lock mechanism 3C. Feeder control section 37 is communicably connected to control device 5 of component mounter 93 via connector 3B, and performs control according to a command from control device 5.

Protrusion 38 protrudes downward from a bottom surface of frame body 34 and extends in the Y-axis direction. Protrusion 38 is inserted into slot 32 of pallet table 31, and thus tape feeder 33 is attached thereto. Upper positioning pin 39 and lower positioning pin 3A are provided at the upper portion of the front face of frame body 34, while being separated from each other in an up-down direction. Upper positioning pin 39 and lower positioning pin 3A are fitted into a positioning hole (not shown) of pallet table 31 to position tape feeder 33. Connector 3B is disposed between upper positioning pin 39 and lower positioning pin 3A. Connector 3B is responsible for supplying power and providing a communication connection to tape feeder 33. When tape feeder 33 is positioned, connector 3B is automatically fitted in a receiving connector (not shown) of pallet table 31.

Lock mechanism 3C is provided at an upper front portion of frame body 34, and is configured using lock member 3D having an approximately F shape. Lock member 3D has support point 3E that is provided substantially at the center of the F-shape and is supported by frame body 34 in an oscillatable manner. Lock member 3D further includes lock lever 3F that extends rearward from support point 3E, is bent, and extends upward, manual operation lever 3G that extends forward from support point 3E, and automatic operation lever 3H that extends upward from support point 3E. In an attachment state of tape feeder 33, lock member 3D is biased by bias spring 3J and oscillates counterclockwise in FIG. 2 about support point 3E. Thus, lock lever 3F protrudes upward from the upper surface of frame body 34, engages with a lock hole (not shown) provided in base 10, and lock mechanism 3C is in a locked state. Accordingly, removal of tape feeder 33 is restricted.

When the worker or conveyance device 7, which will be described later, inserts and attaches tape feeder 33 into slot 32, lock lever 3F comes into contact with base 10 to be automatically lowered, and is brought into a release state in which lock lever 3F is accommodated in frame body 34. Thus, lock mechanism 3C is temporarily unlocked. When the worker removes tape feeder 33, the worker operates manual operation lever 3G upward to oscillate lock member 3D in the clockwise direction in FIG. 2, thereby releasing lock mechanism 3C. When tape feeder 33 is removed, conveyance device 7 operates automatic operation lever 3H to release lock mechanism 3C. Protrusion 38, upper positioning pin 39, lower positioning pin 3A, connector 3B, and lock mechanism 3C are a form of an attachment section in which tape feeder 33 is detachably attached to component mounter 93. The applicant of the present application discloses a detailed configuration example of tape feeder 33 in WO 2019/239474.

### 3. Configuration of Suction Nozzle 45

Next, a configuration of suction nozzle 45 will be described with reference to FIG. 3. Suction nozzle 45 includes body shaft 451, flange 452, nozzle shaft 454, and identification code 455. Body shaft 451 is formed in a cylindrical shape. Flange 452 is formed in a circular plate shape having a larger diameter than that of body shaft 451, and is coupled to one end side (a lower side in FIG. 3) in an axial direction of body shaft 451. Notch 453 that is recessed toward the center side is formed in a part of an outer peripheral edge of flange 452. Notch 453 is for fixing a rotation angle around the axis when suction nozzle 45 is held by nozzle tool 44, or for measuring the rotation angle.

Nozzle shaft 454 is formed in a circular tube shape extending in the axial direction from body shaft 451. Nozzle shaft 454 is a portion where an opening of a distal end portion thereof comes into contact with a component and performs suction pickup. Nozzle shaft 454 is configured to be movable back and forth in the axial direction with respect to body shaft 451. Nozzle shaft 454 is biased in a direction advanced from body shaft 451 by an elastic member (not shown). When a load toward body shaft 451 is applied to the distal end portion, nozzle shaft 454 retreats to an inside of body shaft 451 against an elastic force of the elastic member. This reduces the shock and the load value acting on the component from suction nozzle 45 during the pickup process and the mounting process.

Identification code 455 is attached to the upper surface of flange 452. Identification code 455 includes, for example, a two-dimensional code, and includes unique information such as the type and individual information of suction nozzle 45. Identification code 455 is appropriately read by a code reader (not shown), and is associated with management information (9A, 9B) described later. Thus, a current position, a current state, usage history, and the like of suction nozzle 45 are managed.

There are multiple types of suction nozzles 45 depending on the size of the component as a pickup target. Suction nozzle 45 for large components is formed with at least nozzle shaft 454 being formed to have a large thickness as compared with suction nozzle 45 for the small component, and an opening of a distal end portion is formed to be large. The multiple types of suction nozzles 45 have at least the same diameter and thickness as flange 452 and have attachment compatibility with each other. Nozzle shaft 454 is not limited to a circular tube shape, and the opening of the distal end portion is not limited to a circular shape. For example, the opening of the distal end portion may be elliptical or gourd-shaped, and nozzle shaft 454 may be formed in a tubular shape having a non-circular cross section such that the shape corresponds to the non-circular opening.

### 4. Configuration of Nozzle Feeder 6

Next, a configuration of nozzle feeder 6 will be described with reference to FIG. 1 and FIGS. 4 to 6. Nozzle feeder 6 is a form of a mounting tool feeder that detachably holds multiple component mounting tools (suction nozzles 45) and enables automatic exchange of the component mounting tools at the exchange position of component mounter 93. Nozzle feeder 6 has substantially the same outer shape as tape feeder 33 except for a width dimension in the X-axis direction, and has attachment compatibility with tape feeder 33. That is, nozzle feeder 6 has substantially the same width dimension as tape feeder 33, or has a width dimension larger than that of tape feeder 33 (about twice the width dimension in the example of FIG. 1), and is detachably attached to one or multiple slots 32 of pallet table 31. Nozzle feeder 6 is used in conveying suction nozzle 45 between a second exchange position of component mounter 93 and a storage area (described later) and in conveying suction nozzle 45 between second exchange positions of multiple component mounters 93.

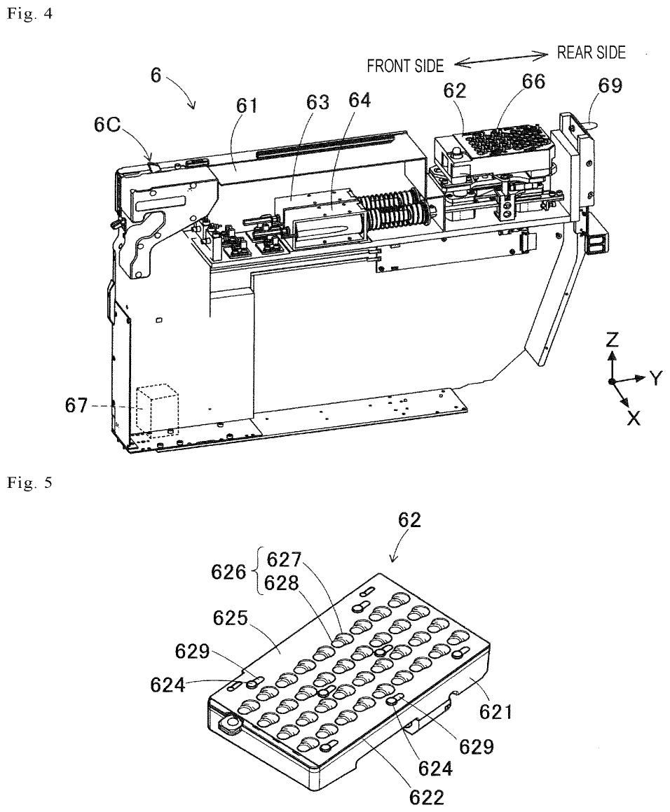

As shown in FIG. 4, nozzle feeder 6 is formed to be thin in the width direction (X-axis direction) by assembling various members to frame body 61 including a side plate. Nozzle feeder 6 includes frame body 61, nozzle holding unit 62, lifting and lowering drive section 63, restriction drive section 64, exchange position 66, feeder control section 67, a protrusion, upper positioning pin 69, a lower positioning pin, a connector, lock mechanism 6C, and the like.

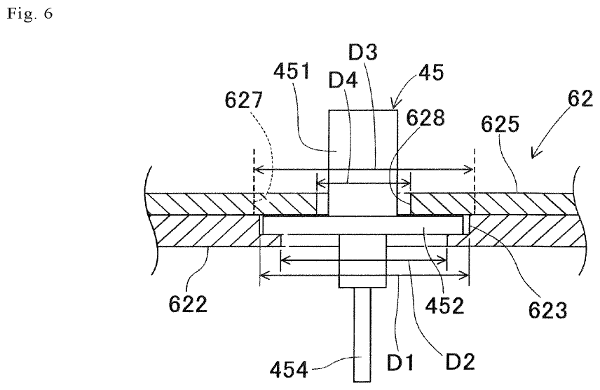

Nozzle holding unit 62 is provided in a liftable and lowerable manner at exchange position 66 set at the rear upper portion of frame body 61. Nozzle holding unit 62 is a form of a mounting tool holding unit that detachably holds multiple component mounting tools (suction nozzles 45). As shown in FIGS. 5 and 6, nozzle holding unit 62 includes base body 621, base plate 622, and cover plate 625. Base body 621 is formed in a rectangular frame shape in plan view. Base body 621 has a height dimension larger than a length dimension of suction nozzle 45 on a distal end side of flange 452, and secures an accommodation space of nozzle shaft 454 of suction nozzle 45.

Base plate 622 is a form of an accommodation member having multiple accommodation holes arranged on a plane and capable of accommodating suction nozzles 45. Base plate 622 is a long rectangular plate-shaped member and is stretched over base body 621. Base plate 622 includes multiple stepped accommodation holes 623 and multiple fitting pins 624. Multiple stepped accommodation holes 623 are arranged in two-dimensional grid points at substantially equal separation distances except for portions close to long sides of base plate 622. Diameter D1 of a large-diameter portion of an upper portion of stepped accommodation hole 623 is larger than the diameter of flange 452 of suction nozzle 45. Further, a height dimension of the large-diameter portion is slightly larger than the thickness of flange 452. Diameter D2 of a small-diameter portion of a lower portion of stepped accommodation hole 623 is smaller than the diameter of flange 452 and larger than the diameter of body shaft 451. Multiple fitting pins 624 are arranged at a portions close to the long sides and portions close to the center of base plate 622, and stand upward.

Cover plate 625 is a form of a restriction member that restricts suction nozzle 45 accommodated in stepped accommodation hole 623 from jumping out at a time other than a time of automatic exchange. Cover plate 625 is a plate-shaped member having substantially the same shape and size as base plate 622, and is disposed above base plate 622 such that cover plate 625 is movable by sliding. Cover plate 625 has multiple restriction holes 626 and multiple long holes 629. Each of multiple restriction holes 626 is disposed above stepped accommodation hole 623. The number of stepped accommodation holes 623 and restriction holes 626 are set larger than the number of suction nozzles 45 of mounting head 43. For example, in a configuration in which mounting head 43 includes 20 suction nozzles 45, the number of stepped accommodation holes 623 and restriction holes 626 is 21 or more. Thus, nozzle feeder 6 can collectively supply all suction nozzles 45 that mounting head 43 automatically exchanges.

Each of restriction holes 626 has a shape in which large-diameter arc portion 627 and small-diameter arc portion 628 are arranged side by side in a long-side direction of cover plate 625. Diameter D3 of large-diameter arc portion 627 is larger than the diameter of flange 452. Diameter D4 of small-diameter arc portion 628 is smaller than the diameter of flange 452 and larger than the diameter of body shaft 451. In restriction hole 626, even when there is a constricted portion between large-diameter arc portion 627 and small-diameter arc portion 628, an opening width dimension of the constricted portion may be larger than the diameter of body shaft 451.

Each of multiple long holes 629 is formed long in the long-side direction of cover plate 625, and is disposed on an upper side of fitting pin 624. Each of multiple long holes 629 is fitted while providing a gap so that fitting pin 624 can move relatively. Thus, cover plate 625 is configured to be movable by sliding in the long-side direction with respect to base plate 622. Further, fitting pin 624 has an increased diameter on the upper side that passes through long hole 629, and prevents cover plate 625 from deviating upward.

Nozzle holding unit 62 is operated to be in an exchangeable state when suction nozzle 45 is automatically exchanged. In the exchangeable state of nozzle holding unit 62, cover plate 625 is moved by sliding, and large-diameter arc portion 627 of restriction hole 626 and stepped accommodation hole 623 vertically overlap each other. Then, flange 452 of suction nozzle 45 to be received is lowered through large-diameter arc portion 627 and is placed on a step portion of stepped accommodation hole 623. Further, flange 452 of suction nozzle 45 to be transferred is lifted from the step portion of stepped accommodation hole 623 through large-diameter arc portion 627.

Meanwhile, at a normal time other than a time of automatic exchange, nozzle holding unit 62 is operated to be in a restriction state in which nozzle holding unit 62 restricts jumping out of held suction nozzle 45. In the restriction state of nozzle holding unit 62 shown in FIG. 6, the slide movement of cover plate 625 is returned to an original position, and small-diameter arc portion 628 of restriction hole 626 and stepped accommodation hole 623 vertically overlap each other. Flange 452 is held and accommodated between the small-diameter portion of stepped accommodation hole 623 and a peripheral edge of small-diameter arc portion 628, so that suction nozzle 45 is prevented from jumping out.

As illustrated in FIG. 4, lifting and lowering drive section 63 and restriction drive section 64 are provided on the front side of nozzle holding unit 62. Lifting and lowering drive section 63 lifts and lowers nozzle holding unit 62 between an upper exchange position and a lower standby position via a transmission mechanism (details not shown). Restriction drive section 64 drives the slide movement of cover plate 625 via a transmission mechanism (details not shown), and switches between the exchangeable state and the restriction state of nozzle holding unit 62. An electric power source, for example, an electromagnetic solenoid can be used as lifting and lowering drive section 63 and restriction drive section 64.

Lifting and lowering drive section 63, which is formed of the electric power source, brings nozzle holding unit 62 into the standby position in an event of power loss, and exhibits a fail-safe function. In other words, since nozzle feeder 6 attached to component mounter 93 does not lift nozzle holding unit 62 to the exchange position even when the power is not supplied as a result of some failure, nozzle holding unit 62 does not interfere with the operations of the other parts. In addition, restriction drive section 64, which is formed of the electric power source, brings nozzle holding unit 62 into the restriction state in the event of power loss, and exhibits a fail-safe function. In other words, even when nozzle feeder 6 is removed from pallet table 31 and the power is not supplied, nozzle feeder 6 is prevented from jumping out of suction nozzle 45.

Feeder control section 67 is disposed at a lower front portion of frame body 61. Feeder control section 67 controls lifting and lowering drive section 63 and restriction drive section 64, and monitors a state of lock mechanism 6C. Feeder control section 67 is communicably connected to control device 5 of component mounter 93 via the connector, and performs control according to a command from control device 5. The protrusion, upper positioning pin 69, the lower positioning pin, the connector, and lock mechanism 6C have the same configuration as those portions of tape feeder 33, and exhibit the same function. Accordingly, the description of these portions will be omitted. The protrusion, upper positioning pin 69, the lower positioning pin, the connector, and lock mechanism 6C are a form of an attachment section that detachably attaches nozzle feeder 6 to component mounter 93.

Exchange position 66 when nozzle feeder 6 is attached to pallet table 31 is at the same position as supply position 36 of tape feeder 33 attached to pallet table 31. Mounting head 43 can move to exchange position 66 of nozzle feeder 6 to sequentially perform the automatic exchange of suction nozzle 45 one by one. Accordingly, exchange position 66 of nozzle feeder 6 attached to pallet table 31 is the predetermined second exchange position inside the device in which mounting head 43 performs the automatic exchange of suction nozzle 45.

Nozzle feeder 6 attached to pallet table 31 lifts nozzle holding unit 62 to the exchange position when suction nozzle 45 is automatically exchanged. Thus, nozzle holding unit 62 is lifted to a height at which mounting head 43 is lowered and suction nozzle 45 can be automatically exchanged. On the other hand, nozzle feeder 6 lowers nozzle holding unit 62 to the standby position and waits at a normal time other than a time of automatic exchange of suction nozzle 45. Thus, nozzle holding unit 62 does not interfere with mounting head 43 and suction nozzle 45 which are lowered for the pickup process.

Nozzle station 48 described above has the same shape as nozzle holding unit 62 of nozzle feeder 6 and has compatibility. Base 10 is provided with lifting and lowering drive section 63 and restriction drive section 64 for driving nozzle station 48. Due to the common use of nozzle station 48 (nozzle holding unit 62), lifting and lowering drive section 63, and restriction drive section 64, the types of constituting members are reduced, which is advantageous in terms of manufacturing. Furthermore, a handling method, management, maintenance, and the like of nozzle station 48 and nozzle holding unit 62 are standardized, and convenience is enhanced.

### 5. Configuration of Production Line 9 of Board Product

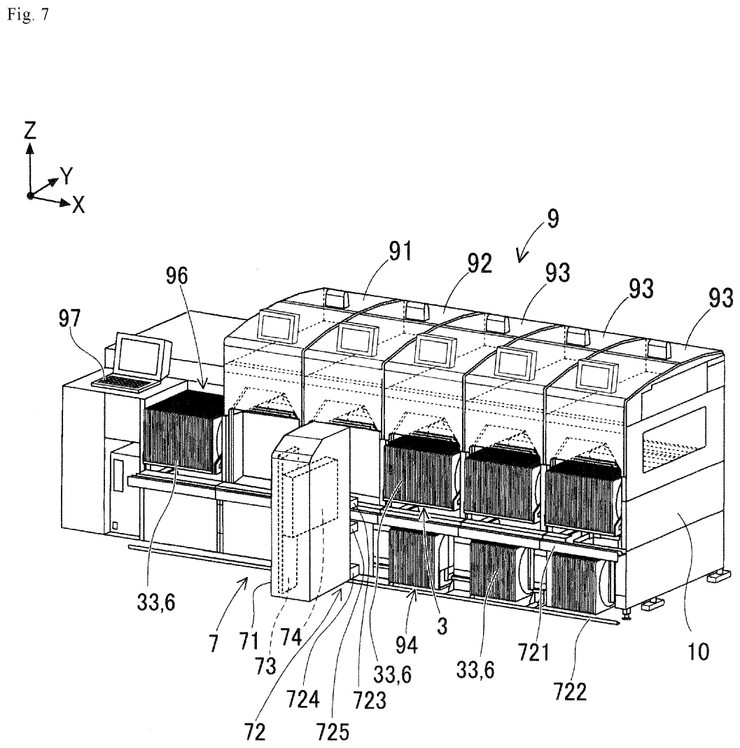

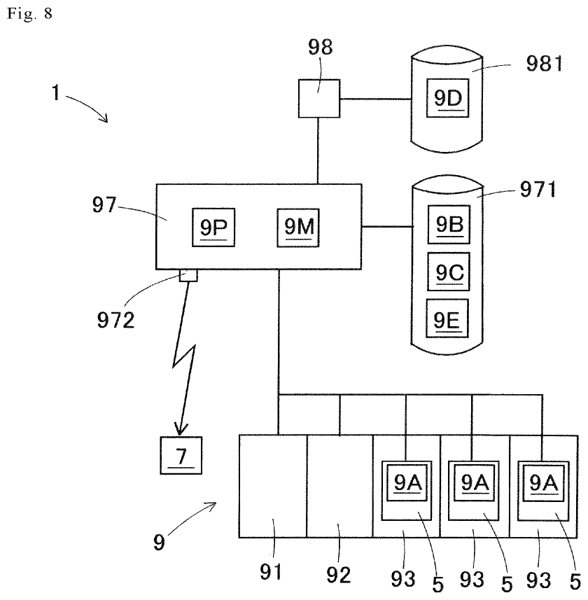

Next, a configuration of production line 9 of the board product will be described with reference to FIG. 7. As indicated by an upper left arrow in FIG. 7, an X-axis direction, a Y-axis direction, and a Z-axis direction of production line 9 are determined in accordance with component mounter 93. In production line 9, multiple board work machines are arranged side by side with each other in the X-axis direction. That is, solder printer 91, printing inspector 92, three component mounters 93, a board visual inspector (not shown), and a reflow machine (not shown) are arranged in the X-axis direction. A line configuration of production line 9 can be changed.

Each of the board work machines performs a predetermined board work on the board. Specifically, solder printer 91 prints paste-like solder in a defined pattern shape on board K. Printing inspector 92 images and inspects a solder printing state of board K. Three component mounters 93 collect components from component supply device 3 and mount the components on the solder of board K. The number of component mounters 93 is not limited to three and can be changed. The board visual inspector images the component mounted on board K and inspects visual state. The reflow machine stabilizes a mounting state of the component by heating and cooling the solder.

Each of component mounters 93 includes in-machine storage area 94 on the lower side of component supply device 3. In-machine storage area 94 includes a storage table having the same shape as pallet table 31. Accordingly, in-machine storage area 94 can detachably store tape feeder 33 and nozzle feeder 6 in the storage table. Further, an attaching/detaching method in the storage table of in-machine storage area 94 is the same as an attaching/detaching method in pallet table 31. In-machine storage area 94 is mainly used in temporarily storing tape feeder 33 and nozzle feeder 6 for exchange to be used from this point, and in temporarily storing tape feeder 33 and nozzle feeder 6 removed from pallet table 31.

Production line 9 is provided with in-line storage area 96 and line management device 97. In-line storage area 96 is disposed adjacent to solder printer 91 and at the same height as component supply device 3 of component mounter 93. In-line storage area 96 has a storage table having the same shape as pallet table 31. Accordingly, in-line storage area 96 can detachably store tape feeder 33 and nozzle feeder 6 in the storage table. An attaching/detaching method in the storage table of in-line storage area 96 is the same as the attaching/detaching method in pallet table 31. In-line storage area 96 is mainly used in storing tape feeder 33 and nozzle feeder 6 and transferring tape feeder 33 and nozzle feeder 6 to and from in-machine storage area 94. Tape feeder 33 and nozzle feeder 6 stored in in-line storage area 96 may be directly conveyed to pallet table 31 without passing through in-machine storage area 94. Line management device 97 is arranged adjacent to in-line storage area 96. Line management device 97 is configured using a computer device.

Further, conveyance device 7 is attached to production line 9. Conveyance device 7 conveys tape feeder 33 and nozzle feeder 6 from a conveyance source to a conveyance destination. As the conveyance source and the conveyance destination, any of pallet table 31 of each of component mounters 93, in-machine storage area 94 of each of component mounters 93, and in-line storage area 96 is appropriately selected and set. Conveyance device 7 includes device housing 71, movement mechanism 72, lifting and lowering mechanism 73, attaching/detaching mechanism 74, and the like. Device housing 71 is formed by using a vertically long case-shaped member, and is open on a side facing component mounter 93 and in-line storage area 96.

Movement mechanism 72 includes middle rail 721, lower rail 722, middle travel portion 723, lower travel portion 724, and non-contact power reception portion 725. Middle rail 721 and lower rail 722 are provided in multiple board work machines and in-line storage area 96. Middle rail 721 and lower rail 722 are arranged in parallel to each other while being vertically separated from each other, and form two trajectory portions extending in the X-axis direction. Middle travel portion 723 and lower travel portion 724 are provided in device housing 71. Middle travel portion 723 is engaged with middle rail 721 in a travelable manner, and lower travel portion 724 is engaged with lower rail 722 in a travelable manner.

At least one of middle travel portion 723 and lower travel portion 724 includes a drive source for travel. A servo motor, a pulse motor, or the like having good controllability of the stop position can be used as the drive source. Non-contact power reception portion 725 is provided between middle travel portion 723 and lower travel portion 724 of device housing 71. Non-contact power reception portion 725 receives power from a non-contact power transmitting section (not shown) provided in the board work machine in a non-contact manner, and supplies power to the drive source. Thus, conveyance device 7 moves along a line-extending direction (X-axis direction) of production line 9.

Lifting and lowering mechanism 73 and attaching/detaching mechanism 74 are provided inside device housing 71. Lifting and lowering mechanism 73 lifts and lowers attaching/detaching mechanism 74 in a range from a height of in-machine storage area 94 to a height of component supply device 3 and in-line storage area 96. A ball screw feed mechanism or a linear motor can be used as lifting and lowering mechanism 73.

Attaching/detaching mechanism 74 performs an attachment/detachment operation of tape feeder 33 and nozzle feeder 6 at the conveyance source and the conveyance destination. More specifically, attaching/detaching mechanism 74 is driven by movement mechanism 72 and lifting and lowering mechanism 73 and directly faces the conveyance source. Next, attaching/detaching mechanism 74 removes tape feeder 33 and nozzle feeder 6 from the directly facing conveyance source and accommodates tape feeder 33 and nozzle feeder 6 inside the mechanism. Next, attaching/detaching mechanism 74 is driven by movement mechanism 72 and lifting and lowering mechanism 73 and directly faces the conveyance destination. Next, attaching/detaching mechanism 74 attaches tape feeder 33 and nozzle feeder 6, which have been accommodated, to the directly facing conveyance destination. Attaching/detaching mechanism 74 can accommodate multiple tape feeders 33 and nozzle feeders 6 inside the mechanism, and the conveyance efficiency is enhanced.

Conveyance device 7 is movable along production line 9 as described above, and conveys suction nozzle 45 by conveying nozzle feeder 6. Conveyance device 7 is used in a replenishment process in which nozzle feeder 6 is taken out from a storage area (hereinafter, “in-machine storage area 94 and in-line storage area 96” are referred to as an “storage area”), is stacked and moved, and is attached to pallet table 31 of component mounter 93. In addition, conveyance device 7 is used in a return process in which nozzle feeder 6 is removed from pallet table 31 of component mounter 93, is stacked and moved, and is conveyed to the storage area. Further, conveyance device 7 is used in a reuse process in which nozzle feeder 6 is removed from pallet table 31 of component mounter 93, is stacked and moved, and is attached to pallet table 31 of another component mounter 93.

### 6. Configuration of Component Mounting System 1

Next, a configuration of component mounting system 1 according to the first embodiment will be described. Component mounting system 1 includes multiple component mounters 93 configuring production line 9 of the board product described above, conveyance device 7 described above, and plan creation section 9P described later. Here, a configuration related to control of component mounting system 1 will be described with reference to FIG. 8. Line management device 97 is communicably connected to control device 5 of each of component mounters 93, and is also communicatively connected to another type of board work machine. Line management device 97 comprehensively manages board work in production line 9.

In each of component mounters 93, control device 5 stores and sequentially updates management information 9A. Management information 9A includes information on the type and the number of suction nozzles 45 held by nozzle feeder 6 positioned at least in component supply device 3 and in-machine storage area 94. Management information 9A may include information on the type and the number of suction nozzles 45 attached to mounting head 43. Further, management information 9A may include unique information of tape feeder 33 positioned in component supply device 3 and in-machine storage area 94, and information on the type and the remaining number of the components supplied by tape feeder 33. Control device 5 controls the mounting work by appropriately referring to management information 9A as well as based on mounting work data 9C (described later).

Line management device 97 stores and sequentially updates management information 9B in attached memory 971. Management information 9B includes information on the type and the number of suction nozzles 45 held by nozzle feeder 6 positioned at least in in-line storage area 96. Further, management information 9B may include unique information of tape feeder 33 positioned in in-line storage area 96, and the information on the type and the remaining number of the components supplied by tape feeder 33. Further, management information 9B may include information on usage history of suction nozzle 45 and tape feeder 33. Examples of the information on the usage history include a past operating time, the number of times of operations, an occurrence status of an operation error, and a performance status of the maintenance.

Line management device 97 stores mounting work data 9C in memory 971. Mounting work data 9C is created for each type of the board product (board K) and for each board work machine. Line management device 97 transmits mounting work data 9C of a board product to be produced next to each of the multiple board work machines in an event of the setup change for changing the type of the board product. In general, mounting work data 9C received by component mounter 93 includes design information on the type of board K as a raw material, the type of the component, a mounting coordinate position, and the like. In the first embodiment, mounting work data 9C includes setup information indicating at least the type of tape feeder 33 or suction nozzle 45 used for each type of board product.

Further, line management device 97 stores maintenance information 9E in memory 971. Maintenance information 9E is information indicating that a recommended timing for maintenance (maintenance timing) of suction nozzle 45 has come, or that the maintenance timing has approached. Line management device 97 compares the usage history of suction nozzle 45 in management information 9B with the predetermined number of times of operations or a predetermined operation time to set a periodic maintenance timing. Line management device 97 may set a temporary maintenance timing when the number of occurrences or an occurrence rate of the operation error of suction nozzle 45 increases. Maintenance information 9E is sequentially updated in accordance with the progress of an operation status of suction nozzle 45.

Line management device 97 is communicably connected to conveyance device 7 using wireless communication section 972, and controls the operation of conveyance device 7. In addition, line management device 97 is communicably connected to production management device 98. Production management device 98 stores and sequentially updates production plan 9D in attached memory 981. Production plan 9D includes at least information indicating the type and production order of the board product to be produced. Production plan 9D may additionally include production quantity and a production deadline of the board product, information indicating a procurement timing of board K as the raw material or the component, an operation plan of production line 9, and a personnel arrangement plan of the worker.

Line management device 97 includes plan creation section 9P and conveyance control section 9M configured using software. Plan creation section 9P acquires production plan 9D, and setup information of mounting work data 9C or maintenance information 9E, and creates a conveyance plan of suction nozzle 45 using conveyance device 7 based thereon. Plan creation section 9P preferably acquires management information (9A, 9B) in addition to production plan 9D, and setup information (mounting work data 9C) or maintenance information 9E, and creates the conveyance plan based thereon.

When plan creation section 9P creates the conveyance plan based on the setup information (mounting work data 9C), plan creation section 9P first recognizes the contents and an performance timing of the setup change for changing the type of the board product in accordance with production plan 9D. Next, based on the setup information (mounting work data 9C) before and after the setup change, plan creation section 9P calculates the quantity by which suction nozzles 45 are excess or insufficient in the event of the setup change for each type of suction nozzle 45. Next, plan creation section 9P creates the conveyance plan including the reuse process of conveying suction nozzle 45 from first component mounter 93 for which it is calculated that suction nozzles 45 are excess to second component mounter 93 for which it is calculated that the same type of suction nozzles 45 are insufficient.

In addition, plan creation section 9P sets, as a part of the conveyance plan, the return process of conveying suction nozzle 45 calculated to be excess in first component mounter 93 to the storage area as necessary. Further, plan creation section 9P sets, as a part of the conveyance plan, the replenishment process of conveying suction nozzle 45 calculated to be insufficient in second component mounter 93 from the storage area as necessary. Then, plan creation section 9P prioritizes the reuse process over the return process and the replenishment process. This makes it possible to minimize the number of suction nozzles 45 required in the event of setup change in production line 9.

Plan creation section 9P can create the conveyance plan for maintenance based on sequentially updated maintenance information 9E. Plan creation section 9P first recognizes suction nozzle 45 for which the maintenance timing has come or the maintenance timing has approached, and component mounter 93 using suction nozzle 45. Next, plan creation section 9P creates the conveyance plan for maintenance including the replenishment process of conveying suction nozzle 45 for exchange from the storage area to component mounter 93 and the return process of conveying suction nozzle 45 to the storage area. The conveyance plan for maintenance is executed in conjunction during the next setup change or is promptly executed immediately after the plan creation. In particular, when the number of occurrences or an occurrence rate of the operation error of suction nozzle 45 increases and the temporary maintenance timing is set, the conveyance plan for maintenance is preferably promptly executed.

Conveyance control section 9M controls conveyance device 7 based on the conveyance plan created by plan creation section 9P. Specifically, conveyance device 7 conveys nozzle feeder 6 holding suction nozzle 45, which is to be used from this point, from the storage area toward component mounter 93, and attaches nozzle feeder 6 to pallet table 31 (replenishment process). In this case, each of component mounters 93 automatically exchanges suction nozzle 45 held by mounting head 43 and not to be used, or suction nozzle 45 for which the maintenance timing has come, with suction nozzle 45 held by nozzle feeder 6 and to be used from this point. Conveyance device 7 carries out nozzle feeder 6 holding suction nozzle 45 not to be used, conveys nozzle feeder 6 to another component mounter 93 (reuse process), or conveys nozzle feeder 6 to the storage area (return process). Further, conveyance device 7 conveys suction nozzle 45 for which the maintenance timing has come to the storage area (return process).

Conveyance control section 9M controls conveyance device 7 based on the conveyance plan to cause conveyance device 7 to convey suction nozzle 45, so that it is possible to convey a limited number of suction nozzles 45 in a planned manner and efficiently operate suction nozzles 45. In addition, conveyance control section 9M can timely convey suction nozzle 45 for which the maintenance timing has come, and can contribute to efficient operation and maintenance of mounting reliability. Functions of plan creation section 9P and conveyance control section 9M will be described in detail with reference to specific examples in the following description of the operation.

### 7. Operation of Component Mounting System 1

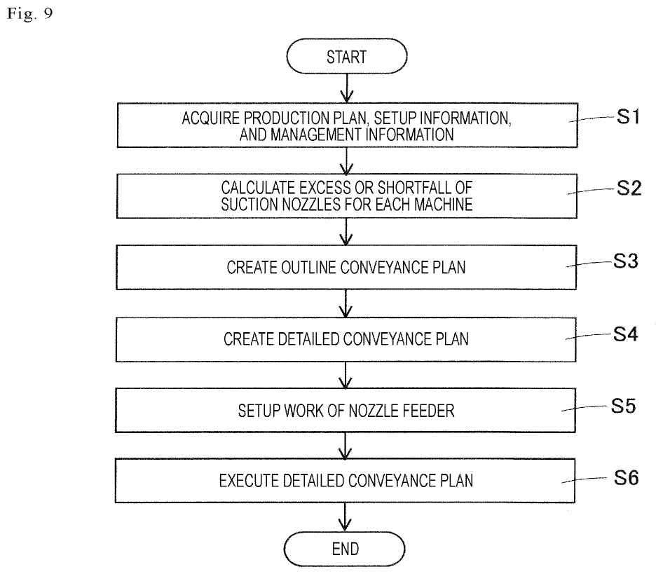

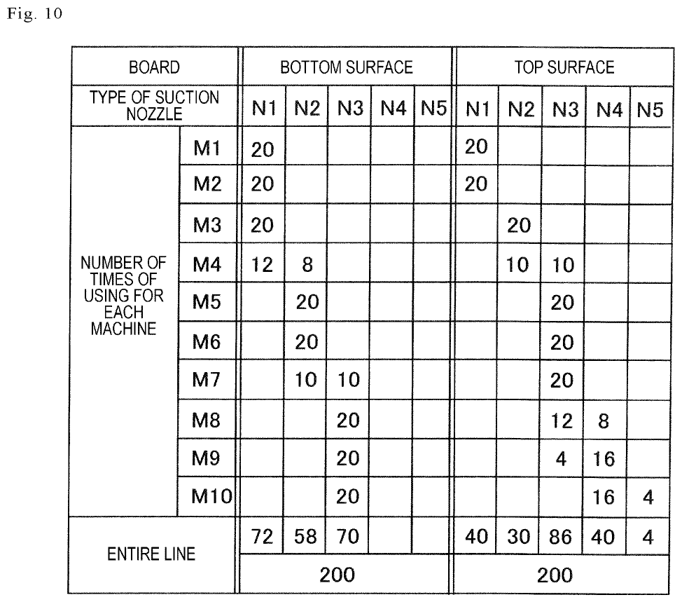

Next, the operation based on the setup information (mounting work data 9C) of component mounting system 1 will be described with reference to FIGS. 9 to 12 using specific examples. In FIGS. 10 to 12, the description of zero which is not important is omitted as appropriate and is blank. Specifically, in production line 9, ten component mounters 93 are arranged side by side, in other words, production line 9 is configured with most upstream first mounter M1 to most downstream tenth mounter M10 being arranged side by side. Each of first mounter M1 to tenth mounter M10 uses 20 suction nozzles 45 in an automatically exchangeable manner. There are five types of suction nozzles 45 from first nozzle N1 to fifth nozzle N5 in ascending order of size of the component as a pickup target. The number of suction nozzles 45 held by nozzle feeder 6 is assumed to be 20 at maximum. In addition, it is assumed that nozzle station 48 is not used in view of automation of the setup change work when the type of the board product is changed.

Then, it is assumed that the production order continuous to a bottom surface and a top surface of board K is set. The bottom surface and the top surface are treated as different types of boards even for the same board K. Of course, it is common to produce different types of boards K in a continuous production order. The number of mounting points of the small-sized component mounted on the bottom surface is relatively large. On the other hand, the number of mounting points of the middle-sized component and the large-sized component is relatively large in the top surface as compared with the bottom surface. As a result, the bottom surface is produced first, and the top surface is produced later. In addition, in the production of each of the bottom surface and the top surface, the small-sized component is preferentially allocated to upstream component mounter 93, and the large-sized component is allocated to downstream component mounter 93. By setting such a mounting order, an influence on the mounting work of the mounted component thereafter is avoided.

An operation flow shown in FIG. 9 is mainly progressed by the control of line management device 97. In step S1 of FIG. 9, plan creation section 9P of line management device 97 acquires production plan 9D from production management device 98. Production plan 9D shows the production order continuous with the bottom surface and the top surface. Plan creation section 9P ends the operations up to Step S4 before the production of the bottom surface is finished and the setup change to the top surface is required. Plan creation section 9P acquires the setup information of the bottom surface and the top surface based on production plan 9D.

As illustrated in FIG. 10, the setup information indicates the number of first to fifth nozzles N1 to N5 used by each of first to tenth mounters M1 to M10. That is, according to the setup information of the bottom surface, first mounter M1, second mounter M2, and third mounter M3 each use 20 first nozzles N1. Fourth mounter M4 uses 12 first nozzles N1 and eight second nozzles N2. Fifth mounter M5 and sixth mounter M6 each use 20 second nozzles N2. Seventh mounter M7 uses ten second nozzles N2 and ten third nozzles N3. Eighth mounter M8, ninth mounter M9, and tenth mounter M10 each use 20 third nozzles N3.

Further, according to the setup information of the top surface, first mounter M1 and second mounter M2 each use 20 first nozzles N1. Third mounter M3 uses 20 second nozzles N2. Fourth mounter M4 uses ten second nozzles N2 and ten third nozzles N3. Fifth mounter M5, sixth mounter M6, and seventh mounter M7 each use 20 third nozzles N3. Eighth mounter M8 uses 12 third nozzles N3 and eight fourth nozzles N4. Ninth mounter M9 uses four third nozzles N3 and 16 fourth nozzles N4. Tenth mounter M10 uses 16 fourth nozzles N4 and four fifth nozzles N5.

Plan creation section 9P acquires management information 9A from each of component mounters 93, and confirms management information 9B. When the bottom surface is being produced, plan creation section 9P confirms that the type and the number of suction nozzles 45 attached to mounting head 43 match the setup information based on management information 9A. In a case of mismatch, plan creation section 9P gives priority to management information 9A and recognizes the type and the number of suction nozzles 45 actually attached to mounting head 43.

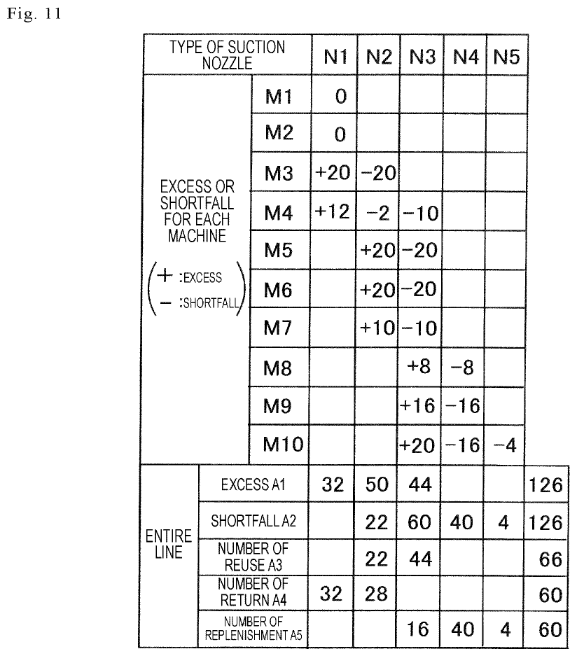

In the next step S2, plan creation section 9P calculates the excess or shortfall of nozzles from first to fifth nozzles N1 to N5 in the event of setup change in first to tenth mounters M1 to M10. A calculation result is indicated by “excess or shortfall for each machine” in FIG. 11, and “+” is attached to the excess, and “−” is attached to the shortfall.

That is, excess or shortfall does not occur in first mounter M1 and second mounter M2. In third mounter M3, there are an excess of 20 first nozzles N1 and a shortfall of 20 second nozzles N2. In fourth mounter M4, there are an excess of 12 first nozzles N1, a shortfall of 2 second nozzles N2, and a shortfall of 10 third nozzles N3. In fifth mounter M5, there are an excess of 20 second nozzles N2 and a shortfall of 20 third nozzles N3. In sixth mounter M6, there are an excess of 20 second nozzles N2 and a shortfall of 20 third nozzles N3. In seventh mounter M7, there are an excess of 10 second nozzles N2 and a shortfall of 10 third nozzles N3. In eighth mounter M8, there are an excess of 8 third nozzles N3 and a shortfall of 8 fourth nozzles N4. In the ninth mounter M9, there are an excess of 16 third nozzles N3 and a shortfall of 16 fourth nozzles N4. In the tenth mounter M10, there are an excess of 20 third nozzles N3, a shortfall of 16 fourth nozzles N4, and a shortfall of 4 fifth nozzles N5.

In the next step S3, plan creation section 9P creates an outline conveyance plan for entire production line 9. More specifically, plan creation section 9P first aggregates the excess and the shortfall for each of first to fifth nozzles N1 to N5 in first to tenth mounters M1 to M10, and calculates excess A1 and shortfall A2 in the entire line. As shown in the field of “entire line” in FIG. 11, excess A1 of first nozzle N1 is 32, and shortfall A2 of first nozzle N1 is zero. For second nozzle N2, excess A1 is 50, and shortfall A2 is 22. For third nozzle N3, excess A1 is 44, and shortfall A2 is 60. For fourth nozzle N4, excess A1 is zero, and shortfall A2 is 40. For fifth nozzle N5, excess A1 is zero, and shortfall A2 is 4. Further, excess A1 and shortfall A2 of all the nozzles combining first to fifth nozzles N1 to N5 are 126, respectively.

Here, in each of first to fifth nozzles N1 to N5, the smaller one of excess A1 and shortfall A2 indicates the number with which the reuse process is available. Accordingly, for each of first to fifth nozzles N1 to N5, plan creation section 9P sets the smaller one of excess A1 and shortfall A2 to number of reuse A3. Number of reuse A3 of second nozzle N2 is 22, and number of reuse A3 of third nozzle N3 is 44. Number of reuse A3 of first nozzle N1, fourth nozzle N4, and fifth nozzle N5 is zero. Accordingly, in contrast to a shortfall of 126 suction nozzles 45 in the entire line, a part of the conveyance plan for reusing 66 (=22+44) suction nozzles 45 is determined.

Next, plan creation section 9P calculates number of return A4 by subtracting number of reuse A3 from excess A1 for first nozzle N1 and second nozzle N2 whose excess A1 is larger than shortfall A2 as targets. Number of return A4 of first nozzle N1 is 32, and number of return A4 of second nozzle N2 is 28. Numbers of returns A4 of third nozzle N3, fourth nozzle N4, and fifth nozzle N5 are zero. Accordingly, a part of the conveyance plan for returning 60 (=32+28) suction nozzles 45 from component mounter 93 to the storage area in the entire line is determined.

Further, plan creation section 9P calculates number of replenishment A5 by subtracting number of reuse A3 from shortfall A2 for third to fifth nozzles N3 to N5 whose excess A1 is smaller than shortfall A2 as a target. Number of replenishment A5 of third nozzle N3 is 16, number of replenishment A5 of fourth nozzle N4 is 40, and number of replenishment A5 of fifth nozzle N5 is 4. Number of replenishment A5 of first nozzle N1 and second nozzle N2 is zero. Accordingly, a part of the conveyance plan in which 60 (=16+40+4) suction nozzles 45 are supplied from the storage area to component mounter 93 in the entire line is determined. That is, in contrast to the shortfall of 126 suction nozzles 45 in the entire line, the number of suction nozzles 45 to be newly prepared is 60, which is less than half.

Accordingly, the outline conveyance plan is created, and the number of suction nozzles 45 as targets of the reuse process, the return process, and the replenishment process performed in entire production line 9 is defined. In a case where suction nozzle 45 for which the maintenance timing has come is conveyed in the event of the setup change, plan creation section 9P performs the return process without performing the reuse process. In addition, plan creation section 9P creates a conveyance plan for supplying shortfall suction nozzles 45 through another reuse process or replenishment process.

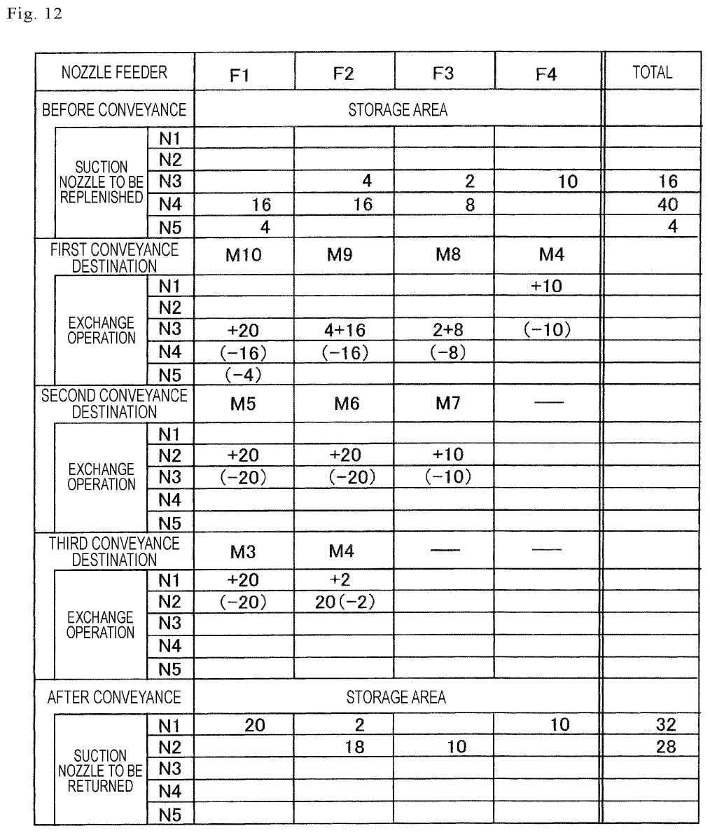

The outline conveyance plan does not define a specific conveyance method of nozzle feeder 6. In step S4, plan creation section 9P creates a detailed conveyance plan for conveying suction nozzle 45 (first to fifth nozzles N1 to N5) using nozzle feeder 6. In the detailed conveyance plan illustrated in FIG. 12, four nozzle feeders 6, that is, first to fourth feeders Fl to F4 are used. The detailed conveyance plan shows multiple conveyance positions to which first to fourth feeders F1 to F4 move, a holding status of suction nozzle 45 at each conveyance position, or the content of an exchange operation. A numerical value denoted by “+” in the exchange operation indicates the number of suction nozzles 45 to be returned from mounting head 43 to nozzle feeder 6. A numerical value described in parentheses with “−” indicates the number of suction nozzles 45 to be supplied from nozzle feeder 6 to mounting head 43.

The detailed conveyance plan is created based on the following creation policies (1) to (4).
(1) If possible, nozzle feeder 6 is continuously used in multiple reuse processes.
(2) If possible, nozzle feeder 6 used in the reuse process is also used in the replenishment process.
(3) If possible, nozzle feeder 6 used in the reuse process is also used in the return process.
(4) If a need arises out of the above (1) to (3), nozzle feeder 6 that is also used in the replenishment process and the return process is used.

Another creation policy can be applied. For example, a third conveyance destination shown in FIG. 12 can be eliminated using larger number of nozzle feeders 6. Further, by making the number of suction nozzles 45 held by nozzle feeder 6 larger than 20 to increase the conveyance position to which one nozzle feeder 6 moves, the number of times of using nozzle feeders 6 can be reduced.

In the detailed conveyance plan illustrated in FIG. 12, the field of “before conveyance” indicates the contents of setup work of (a) to (d) described below in which suction nozzle 45 to be supplied is held by nozzle feeder 6.
(a) In first feeder F1, 16 fourth nozzles N4 and four fifth nozzles N5 are held.
(b) In second feeder F2, four third nozzles N3 and 16 fourth nozzles N4 are held.
(c) In third feeder F3, two third nozzles N3 and eight fourth nozzles N4 are held.
(d) In fourth feeder F4, ten third nozzles N3 are held.

In step S5, conveyance control section 9M requests the worker to perform the setup work of (a) to (d) before executing the detailed conveyance plan. The worker who has received the request performs the setup work of first to fourth feeders F1 to F4, and sets them in the storage area. Conveyance control section 9M confirms that the setup work of first to fourth feeders F1 to F4 is ended by referring to the management information (9A, 9B).

In the next step S6, when the timing of the setup change from the bottom surface to the top surface arrives, conveyance control section 9M controls conveyance device 7 based on the detailed conveyance plan illustrated in FIG. 12. As a result, third to tenth mounters M3 to M10 can attach suction nozzle 45 to be used for the top surface to mounting head 43 through automatic exchange, and can prepare the mounting work of the top surface. First mounter M1 and second mounter M2 do not need the automatic exchange of suction nozzle 45.

Conveyance device 7 conveys not only nozzle feeder 6 but also tape feeder 33 in the event of the setup change. Conveyance device 7 performs the following procedures (A) to (C) when nozzle feeder 6 is attached to pallet table 31 of component mounter 93.
(A) Nozzle feeder 6 is attached to empty slot 32.
(B) When there is no empty slot 32, nozzle feeder 6 is attached to slot 32 which is temporarily empty in exchange of tape feeder 33.
(C) When there is no empty slot 32 and there is no exchange of tape feeder 33, one of tape feeders 33 is temporarily removed, nozzle feeder 6 is attached, and tape feeder 33 is attached again after nozzle feeder 6 is removed.

In the detailed conveyance plan illustrated in FIG. 12, the fields of first to third conveyance destinations indicate the order of the conveyance positions to which nozzle feeder 6 moves, and the field of “after conveyance” indicate that nozzle feeder 6 is returned to the storage area. First feeder F1 for which the setup work is finished is conveyed from the storage area to tenth mounter M10 as the first conveyance destination. First feeder F1 supplies 16 fourth nozzles N4 and four fifth nozzles N5 to mounting head 43 in tenth mounter M10, and receives 20 third nozzles N3 from mounting head 43. First feeder F1 is further conveyed to fifth mounter M5 as the second conveyance destination, 20 third nozzles N3 are supplied to mounting head 43, and 20 second nozzles N2 are received from mounting head 43. First feeder F1 is further conveyed to third mounter M3 as the third conveyance destination, 20 second nozzles N2 are supplied to mounting head 43, and 20 first nozzles N1 are received from mounting head 43. First feeder F1 is finally returned to the storage area, and is stored in a state where 20 first nozzles N1 are held.

Second feeder F2 is conveyed from the storage area to ninth mounter M9, 16 fourth nozzles N4 are supplied to mounting head 43, and 16 third nozzles N3 are received from mounting head 43. The number of third nozzles N3 is 20 in total by adding 16 pieces received to the original four pieces. Second feeder F2 is further conveyed to sixth mounter M6, 20 third nozzles N3 are supplied to mounting head 43, and 20 second nozzles N2 are received from mounting head 43. Second feeder F2 is further conveyed to fourth mounter M4, two second nozzles N2 are supplied to mounting head 43, and two first nozzles N1 are received from mounting head 43. Second feeder F2 is finally returned to the storage area, and is stored in a state where two first nozzles N1 and 18 second nozzles N2 are held.

Third feeder F3 is conveyed from the storage area to eighth mounter M8, eight fourth nozzles N4 are supplied to mounting head 43, and eight third nozzles N3 are received from mounting head 43. The number of third nozzles N3 is ten in total by adding eight pieces to the original two pieces. Third feeder F3 is further conveyed to seventh mounter M7, ten third nozzles N3 are supplied to mounting head 43, and ten second nozzles N2 are received from mounting head 43. Third feeder F3 is finally returned to the storage area, and is stored in a state where ten second nozzles N2 are held.

Fourth feeder F4 is conveyed from the storage area to fourth mounter M4, ten third nozzles N3 are supplied to mounting head 43, and ten first nozzles NI are received from mounting head 43. Fourth feeder F4 is returned to the storage area without being conveyed to another mounter, and is stored in a state where ten first nozzles N1 are held.

As described above, first feeder F1 and second feeder F2 are used in the replenishment process, the two reuse processes, and the return process. Third feeder F3 is used in the replenishment process, the one reuse process, and the return process. Fourth feeder F4 is used in the replenishment process and the return process, and is not used in the reuse process. As described above, conveyance device 7 conveys suction nozzles 45 (first to fifth nozzles N1 to N5) to third to tenth mounters M3 to M10, and each of mounting heads 43 performs the automatic exchange of suction nozzles 45 (first to fifth nozzles N1 to N5), so that the exchange of suction nozzles 45 in the event of the setup change is performed in a fully automatic manner.

Plan creation section 9P may create a conveyance plan including the return process and the replenishment process and not including the reuse process. For example, plan creation section 9P creates a conveyance plan for causing nozzle feeder 6 allocated one by one to each of component mounters 93 to perform the replenishment process and the return process. According to the conveyance plan, first feeder F1 allocated to third mounter M3 is conveyed to third mounter M3 in a state where 20 second nozzles N2 are held. Then, first feeder F1 supplies 20 second nozzles N2 to mounting head 43 in third mounter M3, and receives 20 first nozzles N1 from mounting head 43. Thereafter, first feeder F1 is returned to the storage area and is stored in a state where 20 first nozzles N1 are held.

Second feeder F2 allocated to fourth mounter M4 is conveyed to fourth mounter M4 in a state where two second nozzles N2 and ten third nozzles N3 are held. Second feeder F2 supplies two second nozzles N2 and ten third nozzles N3 to mounting head 43 in fourth mounter M4, and receives twelve first nozzles N1 from mounting head 43. Thereafter, second feeder F2 is returned to the storage area and is stored in a state where 12 first nozzles N1 are held. Also in fifth to tenth mounters M5 to M10, nozzle feeder 6 allocated to each mounter performs the replenishment process and the return process. In the aspect, since 126 suction nozzles 45 corresponding to shortfall A2 of all the nozzles of the entire line are prepared in advance, exchange of suction nozzle 45 in the event of setup change is performed in a fully automatic manner.

Further, when a conveyance plan for maintenance based on maintenance information 9E is created, plan creation section 9P directly creates a detailed conveyance plan. That is, plan creation section 9P creates a conveyance plan for maintenance for conveying nozzle feeder 6 holding suction nozzle 45 to be replenished toward component mounter 93 using suction nozzle 45 whose maintenance timing has come or approached. As described above, the conveyance plan for maintenance is executed in conjunction in the event of the setup change, or is promptly executed without waiting for the timing of the setup change.

When the conveyance plan for maintenance is promptly executed, conveyance control section 9M requests the worker to perform setup work for holding supply suction nozzle 45 to be replenished in nozzle feeder 6 at the time when the plan is created. When nozzle feeder 6 is setup and set in the storage area, conveyance control section 9M controls conveyance device 7 and executes the conveyance plan for maintenance. Thus, nozzle feeder 6 is attached to pallet table 31 of component mounter 93. Component mounter 93 immediately performs the automatic exchange of suction nozzle 45 or measures the timing to perform the automatic exchange. For example, component mounter 93 can perform the automatic exchange of suction nozzle 45 using a time period in which the conveyance of board K is delayed and the mounting work is paused.

In component mounting system 1 according to the first embodiment, plan creation section 9P creates the conveyance plan of suction nozzles 45 (first to fifth nozzles N1 to N5) based on production plan 9D of the board product and the setup information (mounting work data 9C) indicating the type and the number of suction nozzles 45 (first to fifth nozzles N1 to N5) used by each of multiple component mounters 93 (first to tenth mounters M1 to M10). According to this, component mounting system 1 can create a conveyance plan in which suction nozzles 45 (first to fifth nozzles N1 to N5) of the type and the number required in production line 9 are conveyed in a planned manner without excess or shortfall and efficiently operated. Further, nozzle feeder 6 is applicable to component mounters 93 (first to tenth mounters M1 to M10) configuring component mounting system 1, and is capable of supplying suction nozzles 45 (first to fifth nozzles N1 to N5) in a exchangeable manner.

### 8. Configuration of Nozzle feeder 6F according to Application Example

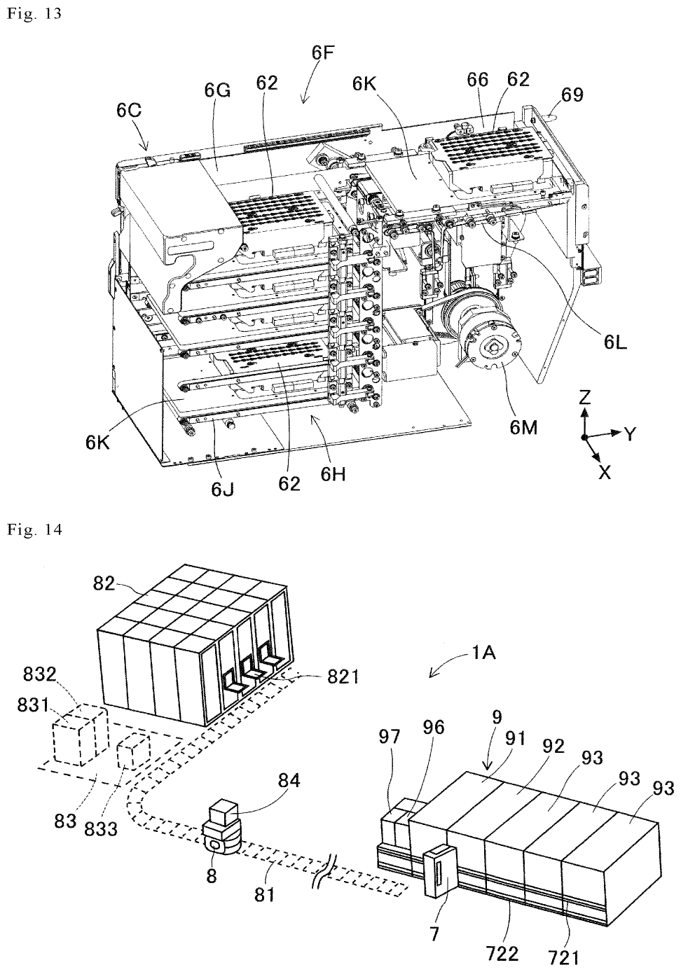

Next, nozzle feeder 6F according to an application example will be described with reference to FIG. 13. Nozzle feeder 6F has substantially the same outer shape as nozzle feeder 6 described in the first embodiment except for the width dimension in the X-axis direction. Nozzle feeder 6F has a width dimension larger than that of nozzle feeder 6 and is detachably attached to multiple slots 32 of pallet table 31. Nozzle feeder 6F is stored in the storage area, and is conveyed by conveyance device 7.

As shown in FIG. 13, nozzle feeder 6F is configured by assembling various members to frame body 6G including a side plate. Nozzle feeder 6F includes frame body 6G, five nozzle holding units 62, accommodation magazine 6H, drawing mechanism 6L, and lifting and lowering mechanism 6M. Each of five nozzle holding units 62 has the same configuration as base plate 622 and cover plate 625 described in the first embodiment, and the number of suction nozzles 45 being held may be different from that of the first embodiment.

Accommodation magazine 6H is provided on the front side (a left side in FIG. 13) inside frame body 6G. Accommodation magazine 6H includes five pairs of rails 6J, which are vertically aligned. Pair of rails 6J extends in a front-rear direction while being separated from each other in a horizontal plane. Pair of rails 6J accommodates support plate 6K in which nozzle holding unit 62 is detachably supported, in a drawable manner. Support plate 6K includes restriction drive section 64 that slides cover plate 625 of nozzle holding unit 62, and lifting and lowering drive section 63 is omitted.

Drawing mechanism 6L draws selected nozzle holding unit 62 together with support plate 6K from accommodation magazine 6H to the horizontal rear (a right side in FIG. 13). Drawing mechanism 6L can be configured by combining, for example, a conveyor belt rotating along a drawing rail, a hook provided on the conveyor belt and configured to lock support plate 6K, and a motor configured to rotate the conveyor belt.

Lifting and lowering mechanism 6M collectively lifts and lowers drawing mechanism 6L, drawn nozzle holding unit 62, and support plate 6K. Lifting and lowering mechanism 6M lifts nozzle holding unit 62 to a height of exchange position 66 when suction nozzle 45 is automatically exchanged. Further, lifting and lowering mechanism 6M lowers nozzle holding unit 62 to avoid interference with the operations of the other members at a normal time other than a time of automatic exchange of suction nozzle 45. In FIG. 13, nozzle holding unit 62, which is second from the bottom, is drawn out by drawing mechanism 6L and lifted to exchange position 66 by lifting and lowering mechanism 6M. When the automatic exchange of suction nozzle 45 in exchange position 66 is ended, nozzle holding unit 62 and support plate 6K are returned to accommodation magazine 6H.

Nozzle feeder 6F includes a protrusion having the same shape as tape feeder 33 and nozzle feeder 6, upper positioning pin 69, a lower positioning pin, a connector, and lock mechanism 6C. Accordingly, the description of these portions will be omitted. Nozzle feeder 6F according to the application example can detachably hold and supply larger number of suction nozzles 45 than nozzle feeder 6. Further, nozzle feeder 6F is not a detachable type but a permanent type, for example, may be permanently installed in component mounter 93 instead of nozzle station 48. According to the aspect, nozzle feeder 6F can supply larger number of suction nozzles 45 than nozzle station 48.

### 9. Component Mounting System 1A according to Second Embodiment

Next, component mounting system 1A according to a second embodiment will be described with reference to FIG. 14 mainly on points different from the first embodiment. As shown in FIG. 14, in the second embodiment, automated guided vehicle 8 is added to the configuration of the first embodiment. Automated guided vehicle 8 functions as a part of conveyance device 7 that conveys the nozzle feeder (6, 6F). Specifically, automated guided vehicle 8 travels between instrument warehouse 82 and conveyance device 7 to convey the nozzle feeder (6, 6F). Further, automated guided vehicle 8 travels between external work area 83 and conveyance device 7 to convey the nozzle feeder (6, 6F).

Automated guided vehicle 8 is generally referred to as an AGV, and travels along travel path 81. Travel path 81 is not limited to a physical substance such as a travel rail, and may be a path virtually set on a floor surface. Automated guided vehicle 8 travels while loading conveyance magazine 84 accommodating multiple tape feeders 33 and the multiple nozzle feeders (6, 6F). For example, conveyance magazine 84 may have a slot having the same shape as slot 32 of pallet table 31. Automated guided vehicle 8 may travel in a state where multiple tape feeders 33 and the multiple nozzle feeders (6, 6F) are directly stacked.

Instrument warehouse 82 loads, stores, and unloads instruments such as tape feeder 33 and the nozzle feeder (6, 6F). Instrument warehouse 82 has an automatic loading/unloading function of automatically loading/unloading tape feeder 33 and the nozzle feeder (6, 6F) when automated guided vehicle 8 arrives at any one of three loading/unloading ports 821. Instrument warehouse 82 is a form of a storage area that is disposed to be separated from production line 9 and stores suction nozzle 45. Plan creation section 9P can create a conveyance plan in which at least one of the conveyance source and the conveyance destination of the nozzle feeder (6, 6F) is set in instrument warehouse 82.

External work area 83 is an area disposed to be separated from production line 9, in which the worker performs various setup work. In external work area 83, nozzle maintenance device 831 (mounting tool maintenance device), nozzle exchange device 832, and placement change device 833 are installed. Further, a feeder setup device for automatically exchanging tape feeder 33 may be installed in external work area 83. Nozzle maintenance device 831 receives nozzle station 48 and nozzle holding unit 62 and automatically performs maintenance of held suction nozzle 45. Nozzle exchange device 832 receives nozzle station 48 and nozzle holding unit 62 and automatically performs exchange of suction nozzle 45. The applicant of the present application discloses a technique example of nozzle maintenance device 831 in Patent Literature 4.

Nozzle maintenance device 831 and nozzle exchange device 832 may be configured to receive the entire nozzle feeder (6, 6F). The maintenance and exchange of suction nozzle 45 may be performed by the worker in external work area 83. The performance history of maintenance and exchange of suction nozzle 45 is transmitted via a communication system (not shown), and is reflected in the update of management information 9B. Plan creation section 9P can create a conveyance plan in which at least one of the conveyance source and the conveyance destination of the nozzle feeder (6, 6F) is set in external work area 83.

Placement change device 833 is disposed close to travel path 81. Placement change device 833 automatically performs place change of instruments such as conveyance magazine 84 between automated guided vehicle 8 and external work area 83. As a result, the nozzle feeder (6, 6F), which is setup by any of nozzle maintenance device 831, nozzle exchange device 832, and the worker, is automatically conveyed from external work area 83 to conveyance device 7. Further, the nozzle feeder (6, 6F) returned from component mounter 93 to conveyance device 7 by the return process is automatically conveyed to external work area 83. Note placement change device 833 may be omitted, and the worker may perform place change of instruments such as conveyance magazine 84.

According to component mounting system 1A according to the second embodiment, the nozzle feeder (6, 6F) is conveyed by automated guided vehicle 8 between instrument warehouse 82 and external work area 83, and conveyance device 7, so that significantly larger number of suction nozzles 45 can be supplied as compared with the first embodiment. Further, since automated guided vehicle 8 conveys the nozzle feeder (6, 6F), labor saving and automation are further promoted.

### 10. Application and Modification of Embodiment

It should be noted that conveyance device 7 automatically operates at any time other than the time of the setup change, and for example, it is possible to automatically exchange tape feeder 33 in which the component runs out along with the progress of the production. Further, plan creation section 9P can omit the outline conveyance plan and can directly create the detailed conveyance plan. Further, plan creation section 9P and conveyance control section 9M may be provided in a computer device other than line management device 97. Management information (9A, 9B) may be stored in a storage device different from the description of the first embodiment.

Furthermore, in the first embodiment, plan creation section 9P targets one production line 9, but the present disclosure is not limited thereto. For example, when the setup change timings of two production lines 9 overlap each other, plan creation section 9P can include, in the conveyance plan, an inter-line reuse process of conveying suction nozzle 45 of component mounter 93 of first production line 9 to component mounter 93 of second production line 9. In the second embodiment, automated guided vehicle 8 may travel to conveyance device 7 provided in each of two production lines 9 to convey the nozzle feeder (6, 6F). Further, nozzle maintenance device 831 and nozzle exchange device 832 may be installed in a movable region of conveyance device 7 in production line 9, and may transfer the nozzle feeder (6, 6F) to and from conveyance device 7. Other various applications and modifications are possible in the first and second embodiments.

### REFERENCE SIGNS LIST

1, 1A: component mounting system, 2: board conveyance device, 3: component supply device, 31: pallet table, 32: slot, 33: tape feeder, 38: protrusion, 4: component transfer device, 43: mounting head, 45: suction nozzle, 48: nozzle station, 5: control device, 6, 6F: nozzle feeder, 62: nozzle holding unit, 622: base plate, 623: stepped accommodation hole, 625: cover plate, 626: restriction hole, 63: lifting and lowering drive section, 64: restriction drive section, 66: exchange position, 6H: accommodation magazine, 6L: drawing mechanism, 6M: lifting and lowering mechanism, 7: conveyance device, 74: attaching/detaching mechanism, 8: automated guided vehicle, 82: instrument warehouse, 83: external work area, 831: nozzle maintenance device, 832: nozzle exchange device, 9: production line, 93: component mounter, 94: in-machine storage area, 96: in-line storage area, 97: line management device, 9A: management information, 9B: management information, 9C: mounting work data, 9D: production plan, 9E: maintenance information, 9P: plan creation section, 9M: conveyance control section, M1 to M10: first to tenth mounter, N1 to N5: first to fifth nozzle, F1 to F4: first to fourth feeder, A1: excess, A2: shortfall, A3: number of reuse, A4: number of return, A5: number of replenishment

1. A component mounting system comprising:
multiple component mounters configured to each hold component mounting tools used in mounting a component on a board at a predetermined exchange position inside the component mounter in an automatically exchangeable manner, the component mounters being arranged side by side with each other to configure a production line for board products;
a conveyance device configured to convey the component mounting tools between a storage area configured to store the component mounting tools either outside the component mounter or inside the component mounter excluding the exchange position and the exchange position of the component mounter, and between the exchange positions of the multiple component mounters; and
a plan creation section configured to create a conveyance plan for the component mounting tools using the conveyance device based on a production plan indicating a type and a production order of the board product, and setup information indicating the types and quantities of the component mounting tools used by each of the multiple component mounters for each type of the board product or maintenance information indicating the maintenance timing of the component mounting tools.

2. The component mounting system according to claim 1, wherein the plan creation section is configured to create the conveyance plan based on the production plan, the setup information or maintenance information, and management information indicating the types and the number of the component mounting tools disposed at the storage area and the exchange position of each of the multiple component mounters.

3. The component mounting system according to claim 1, wherein the plan creation section is configured to calculate excess or shortfall of the component mounting tools used by each of the multiple component mounters for each type of the component mounting tools based on the setup information when the type of the board product is changed in accordance with the production plan, and create the conveyance plan including a reuse process of conveying the component mounting tools from a first component mounter for which it is calculated that the component mounting tools are excess to a second component mounter for which it is calculated that the same type of the component mounting tools are insufficient.

4. The component mounting system according to claim 3, wherein the plan creation section is configured to prioritize the reuse process over a return process of conveying the component mounting tools calculated to be excess in the first component mounter to the storage area and a replenishment process of conveying the component mounting tools calculated to be insufficient in the second component mounter from the storage area.

5. The component mounting system according to claim 1, wherein the plan creation section is configured to calculate excess or shortfall of the component mounting tools used by each of the multiple component mounters for each type of the component mounting tools based on the setup information when the type of the board product is changed in accordance with the production plan, and create the conveyance plan including a return process of conveying the component mounting tools of a type calculated to be excess in a first component mounter from the first component mounter to the storage area and a replenishment process of conveying the component mounting tools of a type calculated to be insufficient in a second component mounter from the storage area to the second component mounter.

6. The component mounting system according to claim 1,
wherein the conveyance device is configured to convey a mounting tool feeder to convey the component mounting tools, and
the mounting tool feeder includes a mounting tool holding unit configured to detachably hold multiple component mounting tools and is detachably attached such that the mounting tool holding unit is disposed at the exchange position of the component mounter.

7. The component mounting system according to claim 6, wherein the mounting tool feeder has attachment compatibility with a component feeder that is detachably attached to the component mounter and is configured to supply the component.

8. The component mounting system according to claim 6, wherein the mounting tool holding unit includes an accommodation member including multiple accommodation holes arranged on a plane and configured to accommodate the component mounting tools, and a restriction member configured to restrict the component mounting tools accommodated in the accommodation holes from jumping out at a time other than a time of automatic exchange.

9. The component mounting system according to claim 8,
wherein the component mounter includes a mounting tool station including the accommodation member and the restriction member and configured to detachably hold the component mounting tools, the mounting tool station being disposed at a first exchange position, and
the mounting tool feeder is detachably attached such that the mounting tool station is disposed at a second exchange position.

10. The component mounting system according to claim 6,
wherein the mounting tool feeder includes
an accommodation magazine configured to accommodate multiple mounting tool holding units, and
an exchange mechanism configured to selectively take out the mounting tool holding unit from the accommodation magazine and dispose the mounting tool holding unit at the exchange position.

11. The component mounting system according to claim 10,
wherein the accommodation magazine is configured to accommodate the multiple mounting tool holding units side by side in a vertical direction, and
the exchange mechanism includes
a drawing mechanism configured to selectively draw the mounting tool holding unit from the accommodation magazine in a horizontal direction, and
a lifting and lowering mechanism configured to lift and lower the drawn mounting tool holding unit to a height of the exchange position.

12. The component mounting system according to claim 6,
wherein the storage area is disposed inside the component mounter excluding the exchange position, or in a line of the production line, and
the conveyance device is configured to move along the production line, take out the mounting tool feeder from the storage area, stack and move the mounting tool feeder, and attach the mounting tool feeder to the component mounter.

13. The component mounting system according to claim 6,
wherein the storage area is disposed to be separated from the production line, and
the conveyance device includes
a feeder conveyance device configured to move along the production line, stack and move the mounting tool feeder, and attach the mounting tool feeder to the component mounter, and
an automated guided vehicle configured to convey the mounting tool feeder between the storage area and the feeder conveyance device.

14. The component mounting system according to claim 13, wherein the automated guided vehicle is configured to convey the mounting tool feeder to a work area in which at least one operation of an exchange operation of attaching the component mounting tools to or detaching the component mounting tools from the mounting tool feeder and a maintenance operation of the component mounting tools is performed, or to a mounting tool maintenance device configured to perform maintenance of the component mounting tools.

15. A mounting tool feeder comprising:
a mounting tool holding unit configured to detachably hold component mounting tools that a component mounter uses in mounting a component on a board, the mounting tool holding unit having the same configuration as a configuration of a mounting tool station disposed at a predetermined first exchange position in which automatic exchange of the component mounting tools is enabled inside the component mounter; and
an attachment section detachably attached to the component mounter such that the mounting tool holding unit is disposed at a predetermined second exchange position inside the component mounter.

16. A mounting tool feeder comprising:
a mounting tool holding unit configured to detachably hold component mounting tools that a component mounter uses in mounting a component on a board;
an accommodation magazine configured to accommodate multiple mounting tool holding units;
an exchange mechanism configured to selectively take out the mounting tool holding unit from the accommodation magazine and dispose the mounting tool holding unit at a predetermined exchange position in which automatic exchange of the component mounting tools is enabled inside the component mounter; and
an attachment section attached to the component mounter.
